(19) United States
(12) Patent Application Publication
(10) Pub. No.: US 2013/0045584 A1
(43) Pub. Date: Feb. 21, 2013

(54) METHOD OF ELIMINATING FRAGMENTS OF MATERIAL PRESENT ON THE SURFACE OF A MULTILAYER STRUCTURE

(71) Applicant: Benedicte Osternaud, Saint Laurant du Pont (FR)

(72) Inventor: Benedicte Osternaud, Saint Laurant du Pont (FR)

(73) Assignee: SOITEC, Crolles Cedex (FR)

(21) Appl. No.: 13/580,860

(22) PCT Filed: Feb. 7, 2011
(86) PCT No.: PCT/FR11/50238

§ 371 Date: Oct. 30, 2012

(30) Foreign Application Priority Data
Feb. 26, 2010 (FR) 1051367

(51) Int. Cl. B08B 3/12; H01L 21/306

(52) U.S. Cl. 438/459; 134/1.3; 257/E21.224; 257/E21.215

(57) ABSTRACT

The invention relates to a method of eliminating fragments of material present on the exposed surface of a first wafer bonded to a second wafer, the method including a step consisting of placing the first wafer in a liquid solution and propagating ultrasonic waves in the solution. The invention also relates to a process for manufacturing a multilayer structure comprising the following successive steps: bonding of a first wafer to a second wafer so as to form a multilayer structure; annealing of the structure; and thinning of the first wafer, including at least one step of chemically etching the first wafer. The process further includes, after the chemical etching step, the elimination of fragments of material present on the exposed surface of the thinned first wafer.

### CROSS-REFERENCE TO RELATED APPLICATION

This is a national phase entry under 35 U.S.C. §371 of International Patent Application PCT/FR2011/050238, filed Feb. 7, 2011, published in English as International Patent Publication WO 2011/104461 A2 on Sep. 1, 2011, which claims the benefit under Article 8 of the Patent Cooperation Treaty to French Patent Application Serial No. 1051367, filed Feb. 26, 2010, the disclosure of which is hereby incorporated herein by this reference in its entirety.

### TECHNICAL FIELD

The present invention relates to the field of production of multilayer semiconductor structures or wafers produced by transferring at least one layer onto a final substrate. Such layer transfer is obtained by bonding, for example, direct bonding, a first wafer (or initial substrate) to a second wafer (or final substrate), the first wafer in general being thinned after bonding. The transferred layer may furthermore comprise all or part of a component or a number of microcomponents.

More precisely, the present invention relates to the problem of material fragments, which appear on the exposed surface of the transferred layer during fabrication of a multilayer structure formed by bonding. This contamination effect has in particular been observed following a chemical etching step carried out on the first wafer of a multilayer structure, for example, during thinning of this first wafer, and particularly when it has not been possible to completely stabilize the bonding interface.

### BACKGROUND

This type of contamination has especially been observed during the fabrication of SOS (silicon-on-sapphire (Al₂O₃)) heterogeneous multilayer structures.

The technique commonly used during the fabrication of multilayer structures to clean the surface of a transferred layer after a chemical thinning step consists in a step of rinsing (or cleaning) by means of a pressurized jet. In general, a pressurized jet of water (or any rinsing solution) is manually applied to the surface of the wafer to be cleaned, this technique sometimes being called “shower cleaning.”

However, the Applicant has observed that the effectiveness of this technique is limited since only a small fraction of the fragments present on the surface of the wafer to be cleaned can be removed thereby. Moreover, it is not currently possible to automate satisfactorily a rinsing step employing a pressurized jet. This technique requires human intervention, which limits industrialization of the rinsing step.

Moreover, ultrasonic baths are commonly used at the present time to clean wafers during a polishing step. Document EP 1 662 560, for example, describes a process for treating an SOI wafer comprising, on its front side, a peripheral lip bordering a circular recess. This process especially comprises removing this lip by polishing, by means of a machine provided for this purpose. This polishing machine in particular comprises a tray containing a rinsing solution. To clean the wafer after polishing, the treated wafer is submerged in the rinsing solution and ultrasonic waves are propagated in the solution.

This cleaning technique generally provides satisfactory results when it is a question of removing grit particles remaining after polishing. The Applicant has however, observed that this type of machine does not satisfactorily remove material fragments present on the exposed surface of a multilayer structure following a chemical etching step.

There is, therefore, at the present time a need to remove, in a simple and effective way, material fragments liable to appear on the surface of a multilayer structure during its fabrication. More particularly, there is a need to effectively clean the first wafer of a multilayer structure, which wafer has been chemically etched.

### DISCLOSURE

One of the aims of the invention is to provide a solution that meets the need described above. For this purpose, the present invention provides a process for removing material fragments present on the exposed surface of a first layer that is bonded to a second wafer, the fragments to be removed being larger than 2 μm, the process comprising a step of submerging at least the first layer in a liquid solution, and a step of propagating ultrasonic waves in the solution, the frequency and power of the ultrasonic waves being set to create a cavitation effect in the liquid solution so as to remove the fragments from the exposed surface.

It will be noted that the size of a fragment can correspond to its length, its width or its diameter.

Advantageously, the process of the invention allows relatively large material fragments deposited on the surface of a multilayer structure during its fabrication and, in particular, during a chemical etching step, to be removed.

The process is also advantageous in that the operating parameters (frequency of the ultrasound, power of the ultrasound, etc.) are easily controllable and reproducible. This process thus allows the cleaning of multilayer structures that have been chemically etched, for example, during a thinning step, to be industrialized.

The material fragments originate, for example, from a prior step of chemically etching the first layer.

The frequency and power of the ultrasonic waves are preferably set depending on the viscosity of the liquid solution. As described in more detail below, it is thus possible to optimize the effectiveness of the removal process of the invention.

Furthermore, the liquid solution may be a rinsing solution. Alternatively, the liquid solution may be an etching solution.

Thus, it is possible to carry out the process of the invention directly in a bath of an etching solution used to chemically etch the first wafer of the multilayer structure. In this case, the etching solution serves as a medium for propagating the ultrasonic waves. In this way, only one tray and one liquid solution are necessary to carry out chemical etching and to remove the material fragments deposited on the surface of the first wafer.

The liquid solution may furthermore comprise at least one of the following solutions: a TMAH solution, a KOH solution and an H₃PO₄ solution.

According to a particular aspect of the invention, at least some of the fragments to be removed are fragments of the first wafer formed during a previous step of chemically etching the first wafer.

Furthermore, the material fragments to be removed may comprise at least one of the following residues: oxide residues originating from an oxide layer located at least at the bonding interface between the first wafer and the second wafer; silicon residues originating from the peripheral edges of the first wafer; and residues from microcomponents, originating from the peripheral edges of the first wafer.

The invention also relates to a process for fabricating a multilayer structure comprising the following steps in succession:
bonding a first wafer to a second wafer so as to form a multilayer structure;
annealing the structure; and
thinning the first wafer, the thinning comprising at least one step of chemically etching the first wafer,

the process being characterized in that it furthermore comprises, after the chemical etching step, removing material fragments present on the exposed surface of the first wafer according to one of the embodiments of the removing process described above.

The process may furthermore comprise a step of oxidizing the first wafer before the bonding step.

This additional oxidation step in particular allows an oxidation layer to be placed at the bonding interface between the first wafer and the second wafer so as to make bonding the two wafers easier.

In a particular embodiment, the chemical etching step is carried out in a bath of an etching solution, and the liquid solution used during the removal of the fragments is the etching solution.

### BRIEF DESCRIPTION OF THE DRAWINGS

Other features and advantages of the present invention will become clear from the description given below with reference to the appended drawings, which illustrate a non-limiting exemplary embodiment therefor. In the figures:

FIGS. 1A to 1D are schematic views showing production of an SOI multilayer structure;

FIG. shows, in the form of a flowchart, the main steps of the production process illustrated in FIGS. 1A to 1D; and

FIG. 3 schematically shows a process for removing material fragments, according to the invention.

### DETAILED DESCRIPTION

The present invention relates, in a general way, to the removal of unwanted material fragments that appear on the exposed surface of a multilayer structure during its fabrication process.

A multilayer or composite structure is produced by bonding a first wafer to a second wafer that supports the first wafer.

The wafers forming a multilayer structure are generally circular and may have various diameters, especially diameters of 100 mm, 200 mm or 300 mm. However, they may be any shape, such as rectangular, for example.

These wafers preferably have a chamfered edge, namely an edge comprising an upper chamfer and a lower chamfer. These chamfers generally have a rounded form. However, the wafers may have chamfers or edge rounding of various forms such as a bevel.

The role of these chamfers is to make handling the wafers easier and to prevent the edge from fragmenting, which could occur if these edges were sharp, such fragments being sources of particulate contamination of the surfaces of the wafers.

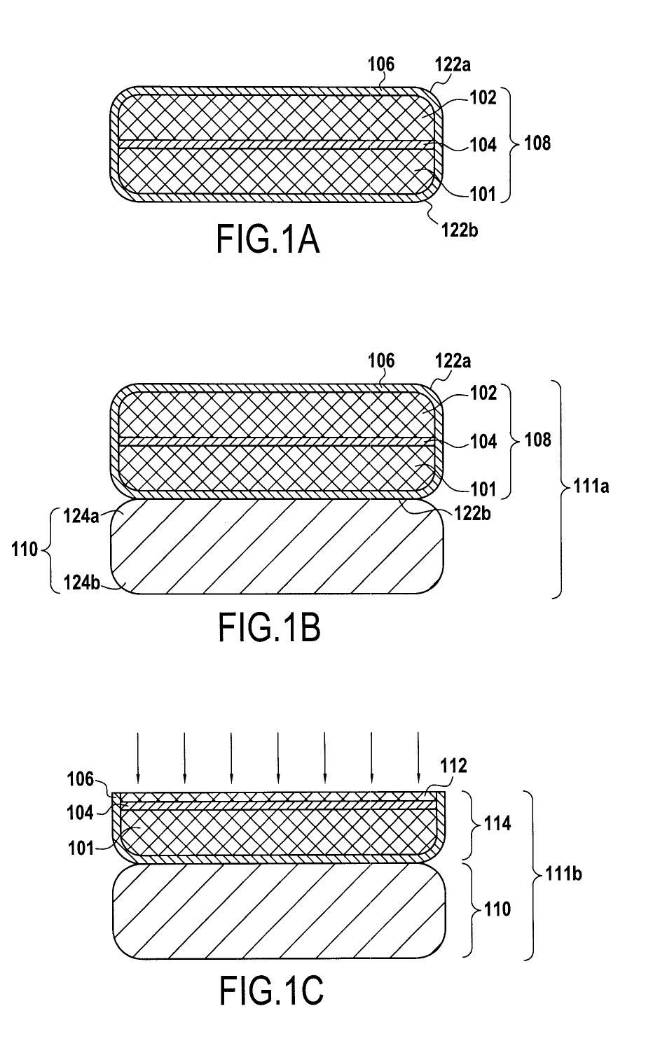

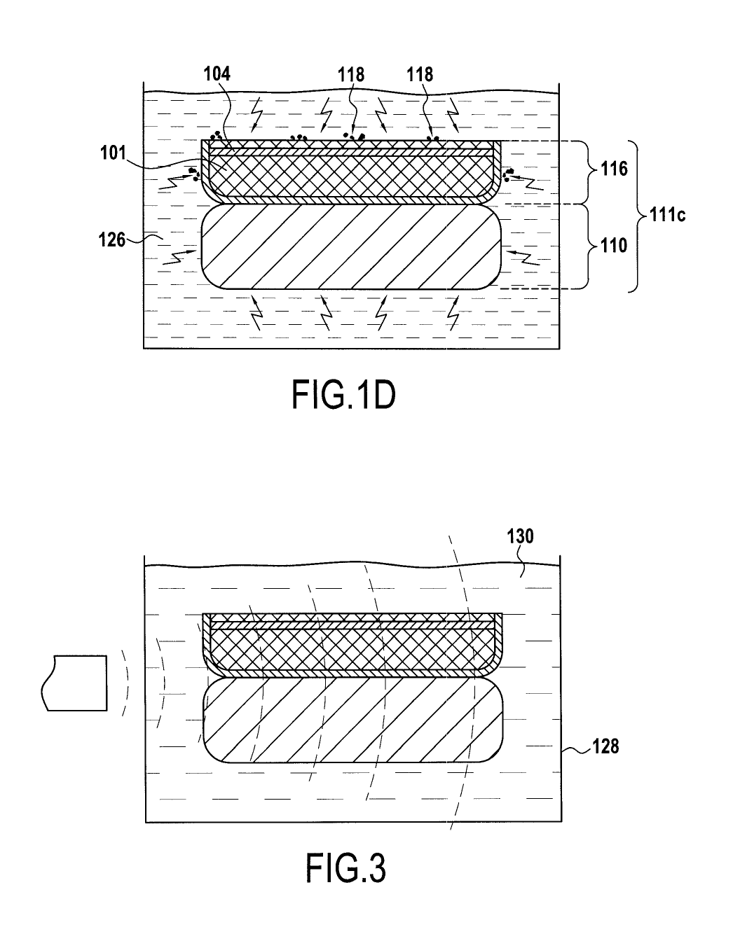

An exemplary process for fabricating a multilayer structure is now described with reference to FIGS. 1A and 1B.

As shown in FIGS. 1A and 1B, a composite structure 111a is formed by joining a first wafer 108 with a second wafer 110.

In this example, the first wafer 108 is an SOI structure comprising a buried oxide layer 104 intermediate between two silicon layers (i.e., the upper layer 101 and the lower layer 102). The second wafer 110 is here made of sapphire.

The first and second wafers 108 and 110 here have the same diameter. They could, however, have different diameters.

Preferably, at least one of the two wafers 108 and 110 has been oxidized before bonding. This oxidation in particular provides an oxide layer intermediate between the two wafers once the bonding has been carried out. This oxidation is obtained by means of a heat treatment in an oxidizing medium. In the example described here, the first wafer 108 is oxidized before bonding, so as to form an oxide layer 106 over the entire surface of the first wafer. Alternatively, it is possible to deposit an oxide layer, called a bonding oxide layer, on the side to be joined of the first wafer 108, before bonding to the second wafer 110, the latter possibly also comprising a surface oxide layer. There is thus a bonding oxide layer at the interface between the first wafer 108 and the second wafer 110, enabling better bonding between these two wafers.

Moreover, the first wafer 108 has a chamfered edge, namely an edge comprising an upper chamfer 122a and a lower chamfer 122b. The second wafer 110 likewise has an edge comprising an upper chamfer 124a and a lower chamfer 124b.

In the example described here, the first wafer 108 and the second wafer 110 are joined by means of direct bonding (also called molecular bonding), this technique being well known to those skilled in the art (step E1).

Other bonding techniques may, however, be used, such as, for example, anodic, metal or adhesive bonding.

It will be recalled that the principle of direct bonding is based on bringing two surfaces into direct contact, i.e., no specific additional material (adhesive, wax, solder) is used. To implement such an operation, the surfaces to be bonded must be sufficiently smooth, free from particulates or contamination, and brought sufficiently close to each other to allow contact to be initiated—typically a distance smaller than a few nanometers. In this case, the attractive forces between the two surfaces are strong enough to cause direct bonding (bonding induced by all the attractive electron interaction forces (Van der Waals forces) between atoms or molecules in the two surfaces to be bonded).

It will be noted that the first wafer 108 may comprise microcomponents (not shown in the figures) on the side to be bonded to the second wafer 110, especially in the case of 3D-integration requiring transfer of one or more layers of microcomponents to a final substrate, or else in the case of circuit transfer, such as, for example, in the fabrication of backlit imagers.

The composite structure 111a is then subjected to a bond-interface-strengthening anneal at a moderate temperature (for example, at 400° C. for 2 hours), this anneal being intended to strengthen the bonding between the first wafer 108 and the second wafer 110 (step E2).

Once this anneal has been carried out, in general, the first wafer 108 is thinned so as to form a transferred layer having a given thickness (for example, about 10 μm) on the supporting wafer. This thinning operation generally comprises a chemical etching operation.

Now, the Applicant has observed that unwanted material fragments appear on the exposed surface of the first wafer 108 following a thinning step involving a chemical etching operation.

In-depth study of these material fragments has allowed their formation mechanism to be understood. The formation mechanism is described in greater detail with regard to FIGS. 1C and 1D, which illustrate an exemplary step of thinning the first wafer 108.

The thinning step in general comprises two separate substeps. The first wafer 108 is first mechanically thinned by a grinder or any other tool able to grind the material of the first wafer (step E3). This first thinning substep removes most of the upper layer 102, only a residual layer 112 (FIG. 1C) remaining.

Next, in a second thinning substep, the residual layer 112 is chemically etched (step E4). This step consists of placing the composite structure 111b in a bath comprising an etching solution 126 (FIG. 1D).

In the example described here, a TMAH solution is used to etch the silicon of the first wafer 108. Other chemical etching solutions may, however, be envisaged, these solutions being chosen, in particular, depending on the composition of the first wafer to be thinned. For example, a KOH or H₃PO₄ solution may be used depending on the circumstances.

The buried oxide layer 104 intermediate between the layers 101 and 102 of the first wafer serves as a stop layer during the chemical etching. Thus, the chemical etching is stopped on the oxide layer 104. The chemical etching thus removes the residual layer 112 remaining after the mechanical thinning.

However, the Applicant has observed that, after the chemical etching operation, material fragments 118 were present on the exposed surface of the first wafer 116. These fragments 118 are typically larger than 2 μm in size.

Studies have shown that these material fragments are debris originating from the edges of the first wafer.

More precisely, the chamfered edges of the first and second wafers cause problems with the bonding of these two wafers at their periphery. Despite the moderate temperature bonding-interface-strengthening anneal, an annular portion of the periphery of the first wafer 108, located in the vicinity of the lower chamfer 122b, does not bond well (and may even not bond at all) to the second wafer 110.

The reduction in the thickness of the first wafer during the steps of mechanical and chemical thinning significantly weakens the edges of the first wafer in the vicinity of the lower chamfer 122b.

Lateral etching during the chemical etching operation weakens the unbonded (or weakly bonded) peripheral zone of the first wafer even more. This additional weakness generally leads to uncontrolled fracturing at the periphery of the thinned first wafer. These fractures cause debris or material fragments to form, which are then liable to deposit on the exposed surface of the thinned first wafer 116.

Thus, oxide-containing and possibly silicon-containing fragments may contaminate the exposed surface of the thinned first wafer 116 (FIG. 1D).

The fracturing, in particular, occurs during the chemical etching in the course of the thinning, when the remaining thickness of the first wafer does not allow it to support its own weight at the periphery. It appears that once this critical stage has been reached, a peripheral portion of the first wafer in the vicinity of the lower chamfer 122b collapses, thus producing the unwanted material fragments 118.

The Applicant has moreover observed that these material fragments 118 are generally relatively large. Typically, these fragments are at least 2 μM in size. The large size of these fragments is especially explained by their formation mechanism, the collapse described above. On account of their large size, these fragments cannot be effectively removed by a conventional ultrasonic cleaning process.

It will also be noted that these fragments 118 may contain circuit residues originating from any microcomponents buried in the first wafer on its side bonded to the second wafer 110.

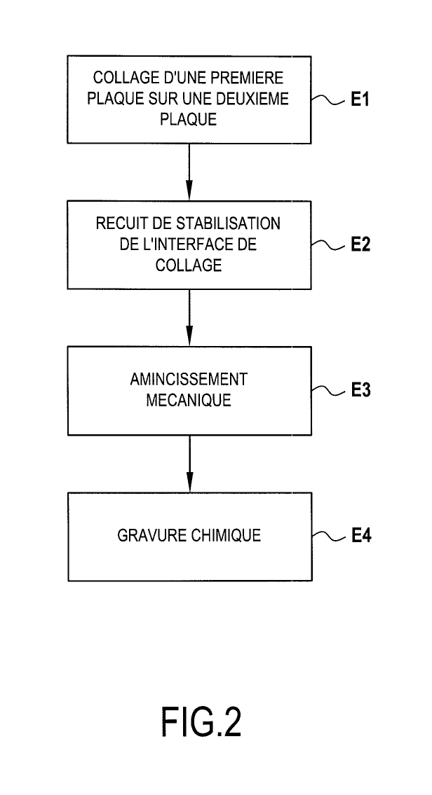

The Applicant has, therefore, developed a process for removing any material fragments that may appear on the surface of a multilayer structure during its fabrication. An exemplary embodiment of the invention is described with reference to FIGS. 2 and 3.

Once the chemical etching has been carried out (FIG. 1D), the multilayer structure 111c is rinsed and then placed in a tray 128 (or dish) containing a rinsing solution 130, as illustrated in FIG. 3. This rinsing solution may, for example, be deionized water (DIW). However, other rinsing solutions may also be envisaged.

Ultrasonic waves, i.e., mechanical and elastic waves, transmitted, for example, by a liquid, with a frequency higher than 20 kHz, are then propagated in the rinsing solution in which the composite structure 111c is submerged.

These ultrasonic waves may be produced, for example, by making piezoelectric transducers oscillate at a given frequency and power (using an ultrasonic cleaner, for example). Other ultrasonic transducers may, however, be envisaged in the context of the invention (magnetostrictive transducers, pneumatic generators, etc.).

The emission of ultrasonic waves under particular conditions leads to what is called an acoustic cavitation effect in the rinsing tray 128. More specifically, the ultrasonic waves cause substantial pressure drops in the rinsing solution 130. When these pressure drops reach a critical threshold, they cause bubbles to form in the rinsing solution 130. These bubbles are commonly called cavitation bubbles.

Since cavitation bubbles are particularly unstable, they implode when they encounter the exposed surface of the thinned first wafer 116. When they implode, these bubbles may emit a shock wave that is sufficiently strong to break up, debond and disperse the material fragments 118 present on the exposed surface of the thinned first wafer 116.

Once debonded from the exposed surface of the thinned first wafer 116, the material fragments 118 are removed by the rinsing solution 130.

The magnitude of the pressure drops leading to this cavitation effect especially depends on the frequency and power of the ultrasonic waves emitted. The Applicant has observed that to obtain a cavitation effect capable of removing fragments that are at least 2 μm in size, the ultrasonic waves used must have a low frequency. In other words, this frequency must lie in a band located between 20 kHz and 1000 kHz. The closer the frequency is to the lower limit of the band (i.e., 20 kHz), the larger the fragments removed by the process of the invention. In a particular embodiment, the frequency of the ultrasonic waves lies between 20 kHz and 500 kHz and even between 20 kHz and 100 kHz. In a variant, the frequency lies between 700 kHz and 1000 kHz.

However, the viscosity of the rinsing solution 130 also has an impact on the magnitude of the pressure drops obtained. This is because, the higher the viscosity of the rinsing solution 130, the more difficult it is to obtain cavitation effect. It is, therefore, recommended to minimize the viscosity of the liquid solution in which the ultrasonic waves propagate. Typically, the viscosity of the liquid solution must be 30 mPa·S (i.e., 30 cP) or less at 25° C. It will be noted that, in this document, the term “viscosity” is understood to mean the dynamic viscosity of a medium.

The frequency and power of the ultrasonic waves will, therefore, be set depending on the viscosity of the rinsing solution 130.

It is also possible to match the temperature of the liquid solution to the situation considered. In particular, the higher the temperature of the solution, the more the viscosity of the latter decreases. It is thus possible to heat the liquid solution in which the ultrasonic waves propagate in order to obtain a viscosity below 30 mPa·S.

Moreover, changing the power of the ultrasonic waves changes the rate at which the material fragments 118 are removed. Thus, the greater the power of the ultrasonic waves, the higher the removal rate. The power is, for example, set to between 600 W and 1200 W.

The table below collates the experimental conditions that may typically be applied to obtain a cavitation effect, making it possible to remove the material fragments 118 on the surface of the thinned first wafer 116:

| | Experimental conditions |
|---|---|
| Tray | Made of stainless steel, quartz or PTFE. |
| Rinsing solution | DIW, TMAH, etc. |
| used | (Additives may be added to the rinsing solution and |
| | the rinsing solution may be made to circulate in the |
| | tray.) |
| Temperature | At room temperature or at 40° C. |
| Power of the | 660 W or 1200 W. |
| ultrasound | |
| Frequency of the | 44 kHz or between 700 kHz and 1000 kHz |
| ultrasound | |
| Orientation of the | Horizontal: adequate effectiveness |
| composite structures | Vertical: good effectiveness |
| in the tray | |
| Duration | 15 min to 20 min |
| Composition of the | An oxide layer (from 500 Å to 2 μm in thickness) |
| observed material | covered with silicon and/or a circuit multilayer. |
| fragments | |

Alternatively, it is possible to carry out the removing process according to the invention, directly in the bath of the etching solution 126, during the chemical etching operation illustrated in FIG. 1D. In this case, the etching solution 126 (a TMAH solution, for example) serves as the medium for propagating the ultrasonic waves and the cavitation is concomitant with the etching action of the etching solution 126.

Once the process for removing fragments according to the invention has been implemented, it is possible to implement a contouring operation in order to remove an annular portion from the periphery of the thinned first wafer 116.

Moreover, the process of the invention is applicable to any type of multilayer structure and, more particularly, to multilayer structures, the wafers of which have chamfered edges (or edge rounding of any shape) and which cannot be heated to high temperatures in order to perfectly stabilize the bonding interface. The invention is, in particular, applicable to SOS structures.

The removing process according to the invention, therefore, advantageously removes material fragments that deposit, or that are liable to deposit, on the surface of a multilayer structure and, more particularly, on the exposed surface of the transferred layer (i.e., the thinned first layer).

The process of the invention is particularly suited to removing particulates that are relatively large in size, i.e., typically being more than 2 μm in size. The process thus removes fragments of a few microns, even a few centimeters, in size.

The process of the invention is also advantageous in that the operating parameters are controllable and reproducible. This technique may thus be optimized and automated for industrial purposes (in contrast to the conventional process of rinsing under a pressurized jet). For example, an ultrasonic bath may advantageously be integrated into a line for producing multilayer structures in order to allow implementation of the process of the invention.

1. A process for removing material fragments larger than 2 μm from an exposed surface of a semiconductor structure having a first layer bonded to a second layer, comprising:
submerging at least the first layer in a liquid solution; and
propagating ultrasonic waves in the liquid solution, the frequency and power of said ultrasonic waves selected to create a cavitation effect in the liquid solution to remove the material fragments larger than 2 μm from the exposed surface.

2. The process of claim 1, further comprising chemically etching the first layer of the semiconductor structure.

3. The process of claim 1, further comprising selecting the frequency and power of the ultrasonic waves based on the viscosity of the liquid solution.

4. The process of claim 1, wherein submerging at least the first layer in a liquid solution comprises submerging at least the first layer in a rinsing solution.

5. The process of claim 1, wherein submerging at least the first layer in a liquid solution comprises submerging at least the first layer in an etching solution.

6. The process of claim 1, wherein submerging at least the first layer in a liquid solution comprises submerging at least the first layer in at least one of a TMAH solution, a KOH solution, and an H₃PO₄ solution.

7. The process of claim 2, wherein chemically etching the first layer of the semiconductor structure comprises forming fragments of the first layer of the semiconductor structure, and wherein propagating ultrasonic waves in the liquid solution comprises removing the fragments of the first layer.

8. The process of claim 1, further comprising removing at least one of an oxide residue originating from an oxide layer located at least at the bonding interface between the first layer and the second layer, a silicon residue originating from the peripheral edges of the first layer, and a residue from microcomponents originating from the peripheral edges of said first layer.

9. A process for fabricating a multilayer structure, comprising:
bonding a first wafer to a second wafer to form a multilayer structure;
annealing the structure;
thinning the first wafer, comprising at least one step of chemically etching the first wafer; and
removing material fragments present on an exposed surface of the thinned first wafer, comprising:
submerging at least the first wafer in a liquid solution; and
propagating ultrasonic waves in the liquid solution, the frequency and power of said ultrasonic waves selected to create a cavitation effect in the liquid solution to remove the material fragments from the exposed surface.

10. The process of claim 9, furthermore comprising oxidizing the first wafer before bonding the first wafer to the second wafer.

11. The process of claim 9, wherein thinning the first wafer solution comprises chemically etching the first wafer in a bath of an etching solution, and wherein propagating ultrasonic waves in the liquid solution comprises propagating ultrasonic waves in the bath of the etching solution.

12. The process of claim 9, further comprising selecting the frequency and power of the ultrasonic waves based on the viscosity of the liquid solution.

13. The process of claim 9, wherein thinning the first wafer solution comprises chemically etching the first wafer in a bath of an etching solution, and wherein submerging at least the first wafer in a liquid solution comprises submerging at least the first wafer in a rinsing solution.

14. The process of claim 9, wherein propagating ultrasonic waves in the liquid solution comprises propagating ultrasonic waves in the rinsing solution.

15. The process of claim 9, wherein submerging at least the first wafer in a liquid solution comprises submerging at least the first wafer in at least one of a TMAH solution, a KOH solution, and an H₃PO₄ solution.

16. A process for removing material fragments from an exposed surface of a semiconductor structure, comprising:
submerging at least a portion of the semiconductor structure in an etching solution; and
propagating ultrasonic waves in the etching solution at a frequency and a power selected to cause cavitation of the liquid solution and remove the material fragments from the exposed surface of the semiconductor structure.

17. The process of claim 16, wherein submerging at least a portion of the semiconductor structure in an etching solution comprises submerging at least a portion of the semiconductor structure in at least one of a TMAH solution, a KOH solution, and an H₃PO₄ solution.

18. The process of claim 16, wherein submerging at least a portion of the semiconductor structure in an etching solution comprises chemically etching the at least a portion of the semiconductor structure and forming fragments of the semiconductor structure, and wherein propagating ultrasonic waves in the etching solution comprises removing the fragments of the semiconductor structure.

19. The process of claim 16, further comprising:
bonding a first wafer to a second wafer to form the semiconductor structure; and
annealing the semiconductor structure.

20. The process of claim 19, further comprising thinning the first wafer.
